(19) United States
(12) Patent Application Publication
(10) Pub. No.: US 2010/0053925 A1
(43) Pub. Date: Mar. 4, 2010

(54) CHIP MOUNT FOR DATA STORAGE DEVICE

(76) Inventor: Chao-Tsung HUANG, Yonghe City (TW)

Correspondence Address: Hershkovitz & Associates, LLC, 2845 Duke Street, Alexandria, VA, 22314, US

(21) Appl. No.: 12/203,625

(22) Filed: Sep. 3, 2008

(51) Int. Cl. H05K 7/04

(52) U.S. Cl. 361/810

(57) ABSTRACT

A chip mount for a data storage device is mounted on a circuit board and has a frame and multiple legs being separately mounted through the frame and being soldered to the circuit board. A chip is mounted in a chip room of the frame and is connected to the circuit board through the legs. The chip mount prevents the chip from being damaged while being soldered to the circuit board. Furthermore, since the chip is removably mounted in the chip room of the frame of the chip mount, the chip is easily replaced with another chip to enlarge a storage capacity or renovate the data storage device. No new data storage device needs to be bought saving money and materials.

### BACKGROUND OF THE INVENTION

1. Field of the Invention

The present invention relates to a chip mount, especially to a chip mount for a data storage device that allows easy exchange of chips for the data storage device.

2. Description of the Prior Arts

With progress of computer technologies, varieties of peripheral devices have been developed. Portable data storage devices such as but not limited to flash drives, portable hard drives and flash memory cards have larger storage capacity and smaller size.

A conventional portable data storage device comprises a circuit board and multiple chips. The circuit board has an electronic circuit and multiple through holes. The electronic circuit is formed over the circuit board. The through holes are formed through the circuit board. The chip may be a control chip, a decoder chip or a memory chip and has multiple terminals. The terminals are respectively mounted through the through holes of the circuit board, are soldered to the circuit board and are electrically connected to the electronic circuit of the circuit board.

Capacity of a portable data storage device depends on the memory chips that are mounted on the circuit board of the portable data storage device. Therefore, a portable data storage device with more memory chips and with a higher chip density has larger capacity.

However, since the chip is small in size, soldering the terminals of the chip to the circuit board is delicate and complicated and may easily fail and damage the chip. Besides, each portable data storage device has a specific capacity that cannot be changed or added to after manufacture. Furthermore, since flash memory may only be written to a finite number of times, or has a finite chip endurance, once a block of memory is unwritable, storage capacity of the device is reduced or nullified. Therefore, a new portable data storage device may have to be bought due to chip endurance, one with larger capacity must be bought for upgrading and frequent replacement of the portable data storage device causes waste of money and materials.

To overcome the shortcomings, the present invention provides a chip mount for a data storage device to mitigate or obviate the aforementioned problems.

### SUMMARY OF THE INVENTION

The main objective of the present invention is to provide a chip mount for a data storage device.

The chip mount is mounted on a circuit board and has a frame and multiple legs being separately mounted through the frame and being soldered to the circuit board. A chip is mounted in a chip room of the frame and is connected to the circuit board through the legs.

The chip mount prevents the chip from being damaged while being soldered to the circuit board. Furthermore, since the chip is removably mounted in the chip room of the frame of the chip mount, the chip is easily replaced with another chip to renovate or enlarge a storage capacity of the data storage device. No new data storage device needs to be bought saving money and materials.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a chip mount of a data storage device in accordance with the present invention;

FIG. 2 is an exploded perspective view of the chip mount in FIG. 1, showing a chip being mounted in the chip mount;

FIG. 3 is an enlarged side view in partial section of the chip mount in FIG. 1, showing the chip being mounted in the chip mount; and

FIG. 4 is an operational perspective view of the chip mount in FIG. 1, showing multiple chip mounts being mounted on a circuit board.

### DETAILED DESCRIPTION OF THE PREFERRED EMBODIMENTS

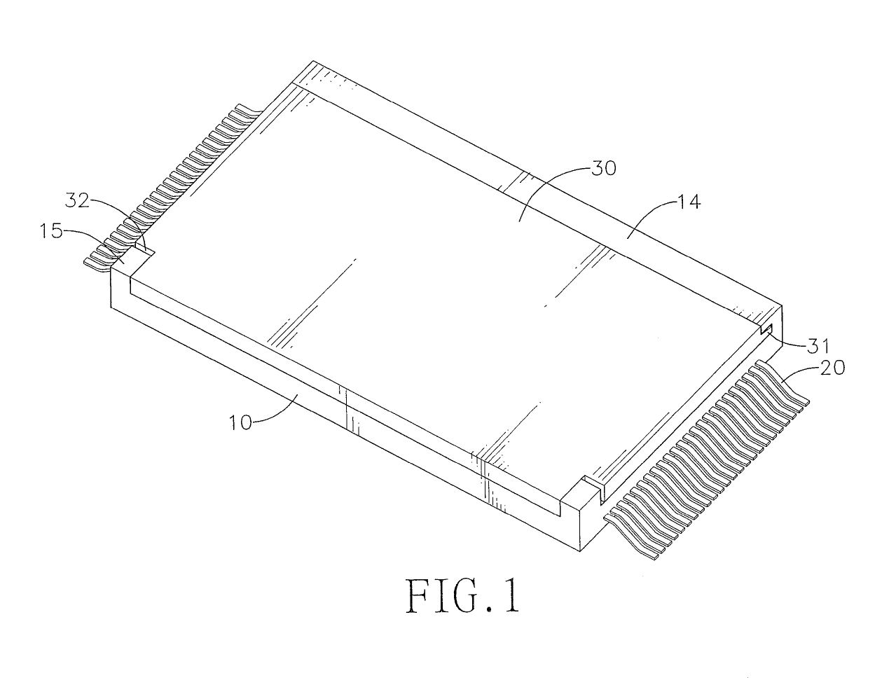

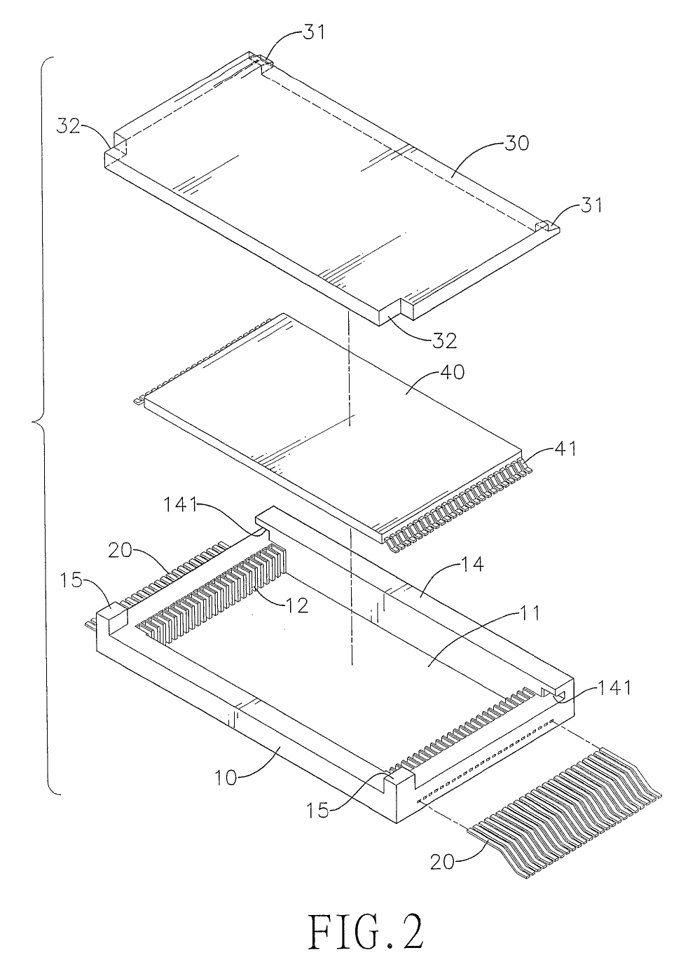

With reference to FIGS. 1 and 2, a chip mount for a data storage device comprises a frame (10) and multiple legs (20) and may comprise a lid (30).

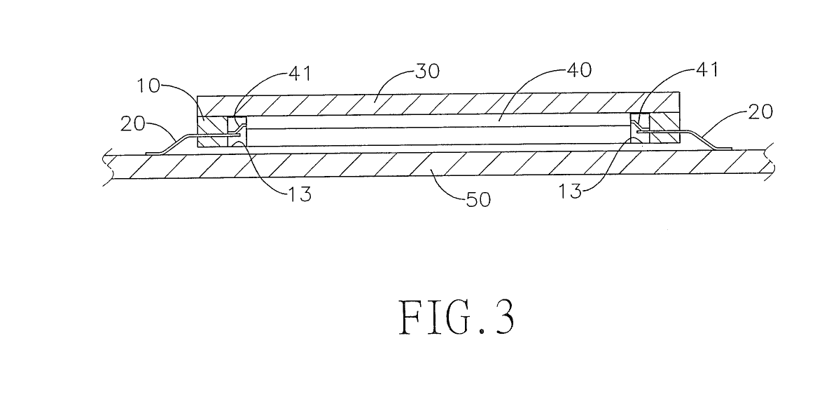

With further reference to FIG. 3, the frame (10) may be an electrical insulator, has a top surface, an inner wall and a chip room (11) and may have multiple partitions (12), multiple leg recesses (13), at least one first positioning protrusion (14) and at least one second positioning protrusion (15). The top surface of the frame (10) has two opposite mounting sides. The chip room (11) is formed between the inner wall of the frame (10). The partitions (12) are separately formed on the inner wall of the frame (10). Each leg recess (13) is formed between two adjacent partitions (12). The at least one first positioning protrusion (14) is formed on and protrudes from one of the mounting sides of the top surface of the frame (10). Each first positioning protrusion (14) has an inner wall and at least one positioning recess (141). The at least one positioning recess (141) is formed in the inner wall of the first positioning protrusion (14) of the frame (10). The at least one second positioning protrusion (15) is formed on and protrudes from the other mounting side of the top surface of the frame (10).

The legs (20) are separately mounted through the frame (10). Each leg (20) has an inner end and an outer end. The inner end of the leg (20) protrudes into the chip room (11) of the frame (10) and may be mounted in the corresponding leg recess (13) of the frame (10) and between two corresponding partitions (12). The outer end of the leg (20) protrudes out of the frame (10).

The lid (30) is securely mounted on the top surface of the frame (10) and has two opposite sides, at least one positioning protrusion (31) and at least one positioning recess (32). The at least one positioning protrusion (31) corresponds to and is mounted in a corresponding positioning recess (141) of the at least one first positioning protrusion (14) of the frame (10). The at least one positioning recess (32) corresponds to and is mounted around a corresponding second positioning protrusion (15) of the frame (10).

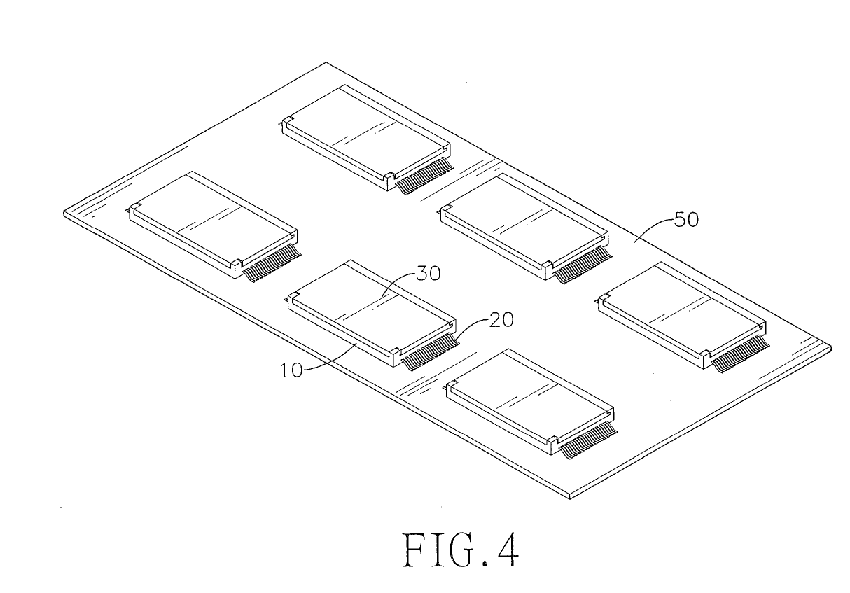

With further reference to FIG. 4, the data storage device has a circuit board (50), multiple chip mounts as described and multiple chips (40). The chip mounts as described are mounted on the circuit board (50). The legs (20) of the chip mounts as described are soldered to and are electrically connected to the circuit board (50). The chips (40) are respectively mounted in the chip mounts as described. Each chip (40) has a perimeter edge and multiple terminals (41). The terminals (41) are mounted on and protrude from the perimeter edge of the chip (40), are respectively mounted in the leg recesses (13) of the frame (10), may be between the partitions (12), and are respectively connected to the legs (20) of the corresponding chip mount. The lids (30) of the chip mounts hold the chip (40) securely in the chip rooms (11) of the frames (10) and protect the chips (40) from being damaged. Therefore, the chips (40) are electrically connected to the circuit board (50) through the legs (20) of the chip mounts as described.

The chip mount for the data storage device as described has the following advantages. The legs (20) of the chip mount are soldered to the circuit board (50) to allow the chip (40) to be electrically connected to the circuit board (50) through the legs (20) of the chip mount and to prevent the chip (40) from being damaged while being soldered to the circuit board (50).

Moreover, since the chip (40) is removably mounted in the chip room (11) of the frame (10) of the chip mount, the chip (40) is easily replaced with another chip (40) that has larger storage capacity to enlarge a storage capacity of the data storage device, to replace malfunctioning chips or renovate expired chips. Therefore, no new data storage device needs to be bought saving money and materials.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A chip mount comprising
a frame having
a top surface;
an inner wall; and
a chip room being formed between the inner wall of the frame; and
multiple legs being separately mounted through the frame and each leg having
an inner end protruding into the chip room of the frame; and
an outer end protruding out of the frame.

2. The chip mount as claimed in claim 1 further has a lid being securely mounted on the top surface of the frame.

3. The chip mount as claimed in claim 1, wherein
the frame further has
multiple partitions being separately formed on the inner wall of the frame; and
multiple leg recesses, and each leg recess being formed between two adjacent partitions; and
the inner end of each leg being mounted in a corresponding leg recess of the frame.

4. The chip mount as claimed in claim 2, wherein
the frame further has
multiple partitions being separately formed on the inner wall of the frame; and
multiple leg recesses, and each leg recess being formed between two adjacent partitions; and
the inner end of each leg being mounted in a corresponding leg recess of the frame.

5. The chip mount as claimed in claim 1, wherein the frame is an electrical insulator.

6. The chip mount as claimed in claim 2, wherein the frame is an electrical insulator.

7. The chip mount as claimed in claim 3, wherein the frame is an electrical insulator.

8. The chip mount as claimed in claim 4, wherein the frame is an electrical insulator.

9. The chip mount as claimed in claim 1, wherein
the top surface of the frame has two opposite mounting sides;
the frame further has at least one first positioning protrusion being formed on and protruding from one mounting side of the top surface of the frame, and each one of the at least one first positioning protrusion having
an inner wall; and
at least one positioning recess being formed in the inner wall of the first positioning protrusion of the frame; and
the lid further has
two opposite sides; and
at least one positioning protrusion corresponding to and being mounted in a corresponding positioning recess of the at least one first positioning protrusion of the frame.

10. The chip mount as claimed in claim 2, wherein
the top surface of the frame has two opposite mounting sides;
the frame further has at least one first positioning protrusion being formed on and protruding from one mounting side of the top surface of the frame, and each one of the at least one first positioning protrusion having
an inner wall; and
at least one positioning recess being formed in the inner wall of the first positioning protrusion of the frame; and
the lid further has
two opposite sides; and
at least one positioning protrusion corresponding to and being mounted in a corresponding positioning recess of the at least one first positioning protrusion of the frame.

11. The chip mount as claimed in claim 3, wherein
the top surface of the frame has two opposite mounting sides;
the frame further has at least one first positioning protrusion being formed on and protruding from one mounting side of the top surface of the frame, and each one of the at least one first positioning protrusion having
an inner wall; and
at least one positioning recess being formed in the inner wall of the first positioning protrusion of the frame; and
the lid further has
two opposite sides; and
at least one positioning protrusion corresponding to and being mounted in a corresponding positioning recess of the at least one first positioning protrusion of the frame.

12. The chip mount as claimed in claim 4, wherein
the top surface of the frame has two opposite mounting sides;
the frame further has at least one first positioning protrusion being formed on and protruding from one mounting side of the top surface of the frame, and each one of the at least one first positioning protrusion having
an inner wall; and
at least one positioning recess being formed in the inner wall of the first positioning protrusion of the frame; and
the lid further has
two opposite sides; and
at least one positioning protrusion corresponding to and being mounted in a corresponding positioning recess of the at least one first positioning protrusion of the frame.

13. The chip mount as claimed in claim 9, wherein
the frame further has at least one second positioning protrusion being formed on and protruding from the other mounting side of the top surface of the frame; and
the lid further has at least one positioning recess corresponding to and being mounted around a corresponding second positioning protrusion of the frame.

14. The chip mount as claimed in claim 10, wherein
the frame further has at least one second positioning protrusion being formed on and protruding from the other mounting side of the top surface of the frame; and
the lid further has at least one positioning recess corresponding to and being mounted around a corresponding second positioning protrusion of the frame.

15. The chip mount as claimed in claim 11, wherein
the frame further has at least one second positioning protrusion being formed on and protruding from the other mounting side of the top surface of the frame; and
the lid further has at least one positioning recess corresponding to and being mounted around a corresponding second positioning protrusion of the frame.

16. The chip mount as claimed in claim 12, wherein
the frame further has at least one second positioning protrusion being formed on and protruding from the other mounting side of the top surface of the frame; and
the lid further has at least one positioning recess corresponding to and being mounted around a corresponding second positioning protrusion of the frame.
